(19) United States
(12) Patent Application Publication
(10) Pub. No.: US 2026/0301583 A1
(43) Pub. Date: Oct. 1, 2026

(54) Electronic device and method for assisting in the planning and dynamic negotiation of aircraft flight plan(s)

(71) Applicant: THALES, Meudon (FR)

(72) Inventors: Alaric BLANQUÉ, MERIGNAC (FR); Bastien BERTHELOT, MERIGNAC (FR); Dominique LATGÉ, TOULOUSE (FR); François MICHEL, MERIGNAC (FR); Annelaure KESSEDJIAN, MERIGNAC (FR)

(21) Appl. No.: 19/574,960

(22) Filed: Mar. 23, 2026

(30) Foreign Application Priority Data
Mar. 31, 2025 (FR) 2503319

(51) Int. Cl. G08G 5/34; G01C 21/20; G06F 30/20

(52) U.S. Cl. CPC G08G 5/34; G01C 21/20; G06F 30/20

(57) ABSTRACT

An electronic device for assisting in planning and dynamic negotiation of aircraft flight plan(s), by machine-to-machine connection with first and second digital twins representative respectively of an air navigation service provider and an air operations officer, including a module for acquiring data impacting planning and negotiation of flight plan(s), a module for optimizing aeronautical routes, a generation module, on a worldwide scale, of an air traffic prediction, an update module for updating the aeronautical routes and traffic prediction, and a negotiation module for negotiating flight plan(s) between the digital twins, using the traffic prediction.

### CROSS-REFERENCE TO RELATED APPLICATION

This application is a U.S. non-provisional application claiming the benefit of French Application No. 25 03319, filed on Mar. 31, 2025, which is incorporated herein by reference in its entirety

### TECHNICAL FIELD OF THE INVENTION

The present invention relates to an electronic device for assisting in planning and dynamic negotiation of aircraft flight plan(s).

The invention also relates to a method for assisting in planning and dynamic negotiation of aircraft flight plan(s).

The invention also relates to a computer program including software instructions which, when executed by a computer, implement such a method.

### BACKGROUND OF THE INVENTION

The invention lies in the technical field of air transport and, more particularly, in the collaboration between air traffic stakeholders during flight planning.

In the state of the art, air traffic stakeholders most often act independently of one another or by collaborating in an improvable manner.

On the one hand, air navigation service providers (ANSPs) face several challenges, namely:
information on air traffic in their area, which is often received too late, in particular about three hours before the departure time of a flight (or more precisely the estimated off-block time (EOBT)), limits their ability to anticipate;
the lack of an effective collaboration tool between air navigation service providers (ANSPs), these most often being limited to using the International Civil Aviation Organization (ICAO) messaging system and the telephone for management and planning;
the lack of a single, up-to-date reference concerning flights, which creates a lack of “single truth” about the real state of air traffic (i.e., a lack of truth common to everyone, i.e., an estimate of the traffic state based on impartial data validated by all air-traffic stakeholders);
the lack of tracking of the schedules produced by air traffic controllers (ATCOs), and
the discontinuity between the air traffic flow manager(s) (FMP-Flow Management Position) and air traffic controllers (ATCOs) regarding overall flow management.

Airline operations officers, also called airline dispatchers, also face other difficulties, namely:
a lack of efficiency in integrating information, such as a runway closure or air traffic management (ATM) data, which reduces their ability to anticipate and overloads them with alerts, so that problem management becomes a priority over planning, leading to a cascade of unanticipated difficulties;
improvisation, often recurrent, of flight plans, due to constraints imposed by air traffic control (ATC) and by weather, which complicates forecasting the required fuel;
poor coordination with air navigation service providers (ANSPs) with a local view, forcing airlines, with a global view, to provide global solutions adapted locally; and
the time required to establish a flight plan, particularly for long-haul flights, often very long, for example, around 45 minutes, which adds additional complexity.

At present, there is no solution capable of effectively aggregating, in planning, and on a worldwide global scale, the constraints affecting air navigation service providers (ANSPs), as well as tangible and intangible airline data, while taking into account the particularities of airspaces throughout the world.

### SUMMARY OF THE INVENTION

The present invention aims to solve this problem and to propose a solution enabling flights to be planned efficiently by integrating, throughout planning, an effective and dynamic negotiation between the different air traffic stakeholders.

To this end, the invention relates to an electronic device for assisting in planning and dynamic negotiation of aircraft flight plan(s), by machine-to-machine connection, with a first digital twin representative of at least one air navigation service provider, and with a second digital twin representative of at least one air operations officer, the device including:
an acquisition, analysis, and update module configured to acquire, analyze, and update data coming from a plurality of distinct sources including at least the digital twins, the data being likely to have an impact on planning and negotiation of flight plan(s);
a creation and optimization module configured, based on the data, to create and optimize aeronautical routes compatible with the air traffic control constraints associated with the data;
a generation module configured to generate, on a worldwide scale, at least one air traffic prediction from the aeronautical routes;
an update module configured to update the aeronautical routes and the at least one air traffic prediction as soon as at least one new datum is acquired or as soon as at least one datum is updated; and
a negotiation module configured to intervene, in the planning phase of flight plan(s), in a negotiation of flight plan(s) between the digital twins, using the air traffic prediction.

The present invention thus makes it possible to simulate, in planning, as time progresses and updates occur, air traffic scenarios serving as a basis for negotiation.

Indeed, the electronic device for assisting in planning and dynamic negotiation of aircraft flight plan(s) according to the present invention plays the central role of a gateway (i.e., platform) for machine-to-machine negotiation between two distinct worlds, namely on the one hand air navigation service providers (ANSPs), and on the other hand, air operations officers, and also as a gateway between the strategic phase of flight planning, up to six months before each flight, and real-time management of air flow, facilitating the transition between flight forecasting and execution.

By means of the machine-to-machine integration according to the invention between airlines and the suppliers (i.e., providers) of air navigation services (ANSPs), the electronic device for assisting in planning and dynamic negotiation of aircraft flight plan(s) according to the present invention is a central tool that enables automation, tracking, and improved efficiency of planning and negotiation process, offering reliable alternatives and reducing the workload of ANSPs, the air navigation service providers (NSPs), in case of new constraints or necessary adjustments.

According to other advantageous aspects of the invention, the electronic device for assisting in planning and dynamic negotiation of aircraft flight plan(s) includes one or more of the following features, taken alone or in all technically possible combinations:
the data include data provided by the digital twins and also context data of a type belonging to the group including:
   surveillance data provided by a cooperative surveillance system for air traffic control;
   aeronautical publications;
   meteorological data;
   event data; and
   historical data;
the negotiation module includes:
   a first interaction entity with the first digital twin representative of at least one air navigation service provider, configured to receive at least one item of information representative of a capacity of the at least one air navigation service provider, the capacity being defined for each control zone of the airspace associated with the at least one air navigation service provider and for a predetermined time period;
   a second interaction entity with the second digital twin representative of at least one air operations officer, configured to receive at least one item of information representative of a demand of the at least one air operations officer, the demand being defined by scheduled or ongoing flights associated with the at least one air operations officer;
   an entity for determining negotiation-aid elements configured to:
      determine, for each air navigation service provider, a demand-of-interest information representative of all flights crossing one of its control zones; and
      determine, for each air operations officer, a capacity-of-interest information grouping the capacities of the zones crossed;
   the determination entity is also configured to estimate the evolution of traffic demand using:
      an optimal filtering belonging to the group including:
      Kalman filtering; and
      particle filtering;
or
   predetermined machine learning;
   the entity for determining negotiation-aid elements is further configured to:
      determine, by searching in a database of situation(s) similar to the current situation, for each air navigation service provider, a capacity solution representative of the capacity that best absorbs the demand of interest; and
      determine, for each air operations officer, a demand solution proposing at least one flight compatible with the capacity of interest, using a predetermined path-finding algorithm and a predetermined weighting based on at least one intention to implement a flight of the air operations officer;
      the negotiation module is further configured to make the negotiation autonomous by applying a predetermined set of rules for processing the capacity solution and/or the proposed demand solution;
   the demand solution is further determined using a predetermined route catalog and a business-rule base specific to airlines, the catalog and the business-rule base being configured beforehand by the at least one air operations officer; and
   the negotiation module further includes:
      a simulation entity of at least one other air navigation service provider not represented by the first digital twin while participating in the capacity of interest; and
      a simulation entity of at least one other air operations officer not represented by the second digital twin while participating in the demand of interest.

The invention also relates to a method for assisting in planning and dynamic negotiation of aircraft flight plan(s), by machine-to-machine connection with a first digital twin representative of at least one air navigation service provider, and with a second digital twin representative of at least one air operations officer, the method being implemented by an electronic device for assisting in planning and dynamic negotiation of flight plan(s), the method including at least one iteration of the following operations:
acquiring, analyzing, and/or updating data coming from a plurality of distinct sources including at least the digital twins, the data being likely to have an impact on planning and negotiation of flight plan(s);
creating and optimizing aeronautical routes compatible with the air traffic control constraints associated with the data;
generating, on a worldwide scale, at least one air traffic prediction from the aeronautical routes;
updating the aeronautical routes and the at least one air traffic prediction, as soon as at least one new datum is acquired or as soon as at least one datum is updated; and
intervening, in the planning phase of flight plan(s), in a negotiation of flight plan(s) between the digital twins, using the air traffic prediction.

The invention also relates to a computer program including software instructions which, when executed by a computer, implement a method for assisting in planning and dynamic negotiation of aircraft flight plan(s) as defined above.

### BRIEF DESCRIPTION OF THE DRAWINGS

The invention will appear more clearly upon reading the following description, given solely by way of non-limiting example, and made with reference to the drawings wherein:

FIG. 1 is a schematic view of an electronic device for assisting in planning and dynamic negotiation of aircraft flight plan(s) according to the present invention;

FIG. 2 is a schematic view illustrating, over time, the machine-to-machine interactions of an electronic device for assisting in planning and dynamic negotiation of aircraft flight plan(s) according to the present invention, with a first digital twin representative of at least one air navigation service provider, and with a second digital twin representative of at least one air operations officer;

FIG. 3 is a flowchart of a method for assisting in planning and dynamic negotiation of aircraft flight plan(s) according to the present invention implemented by the device shown in FIG. 1; and

FIGS. 4 and 5 are different views illustrating optional steps of the method for assisting in planning and dynamic negotiation of aircraft flight plan(s) shown in FIG. 3, according to an autonomous negotiation mode.

### DETAILED DESCRIPTION

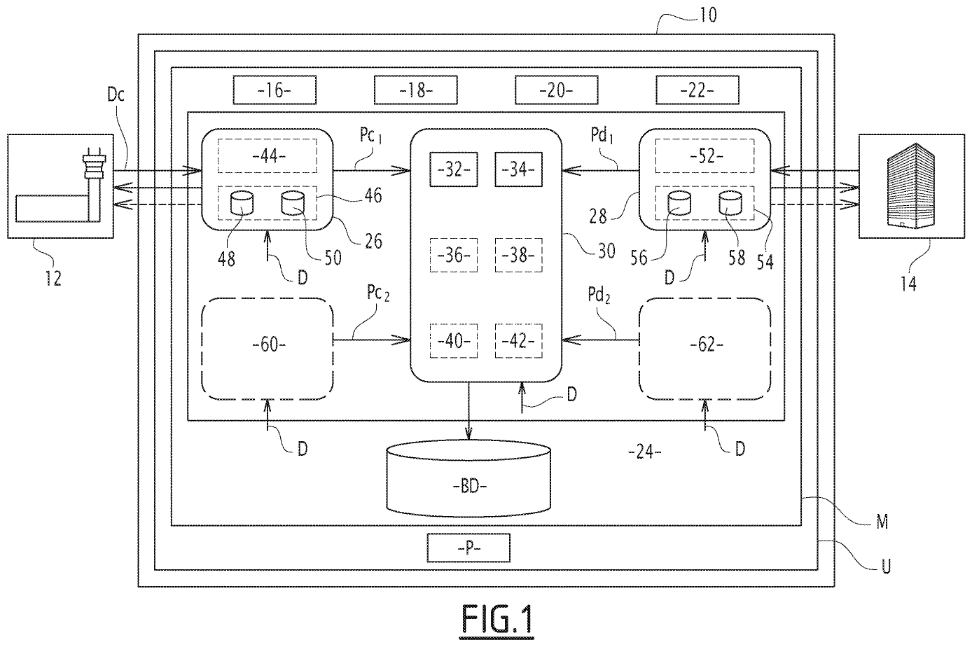

FIG. 1 schematically illustrates a non-limiting example of an electronic device 10 for assisting in planning and dynamic negotiation of aircraft flight plan(s) according to the present invention.

According to this embodiment, electronic device 10 for assisting in planning and dynamic negotiation of aircraft flight plan(s) is intended to be connected, machine-to-machine, to a first digital twin 12 representative of at least one air navigation service provider (ANSP) on the one hand, and on the other hand to a second digital twin 14 representative of at least one air operations officer (i.e., also called an airline dispatcher).

Electronic device 10 for assisting in planning and dynamic negotiation of aircraft flight plan(s) according to the present invention firstly includes an acquisition, analysis, and update module 16 configured to acquire, analyze, and update data coming from a plurality of distinct sources including at least the digital twins, the data being likely to have an impact on planning and negotiation of flight plan(s).

Electronic device 10 for assisting in planning and dynamic negotiation of aircraft flight plan(s) according to the present invention also includes a creation and optimization module 18 configured, based on the data, to create and optimize aeronautical routes compatible with air traffic control constraints.

It should be noted that, by aeronautical route, what is meant hereinafter is a flight defined by a departure airport and an arrival airport, a route being a simplified version of an associated flight plan, the flight plan being associated with a legal aspect relating to the trajectory used on a specific date and a temporal aspect related to the date and time slot of the flight.

In other words, creation and optimization module 18 is configured to automatically create, as early as possible, optimized routes compatible with air traffic control (ATC) constraints, and likely to be used by airlines. The level of detail of the proposed routes evolves with information updated over time: ANSP constraints, military activities, NOTAM (Notice to Airmen) messages, weather forecasts leading toward the definition of a 4D trajectory (i.e., in four dimensions including three spatial dimensions and one temporal dimension).

Electronic device 10 for assisting in planning and dynamic negotiation of aircraft flight plan(s) according to the present invention also includes a generation module 20 configured to generate, on a worldwide scale, at least one air traffic prediction from the aeronautical routes.

In other words, generation module 20 provides an overall view (i.e., a complete view) of future air traffic, allowing scenarios to be simulated and sector constraints to be adjusted according to forecasts, while providing key performance indicators (KPIs) to manage hotspots. Such a simulation of future air traffic serves as a basis for negotiation in the planning phase.

Electronic device 10 for assisting in planning and dynamic negotiation of aircraft flight plan(s) according to the present invention further includes an update module 22 configured to update the aeronautical routes and the at least one air traffic prediction, as soon as at least one new datum is acquired or as soon as at least one datum is updated.

Electronic device 10 for assisting in planning and dynamic negotiation of aircraft flight plan(s) according to the present invention also includes a negotiation module 24 configured to intervene, in the planning phase of flight plan(s), in a negotiation of flight plan(s) between the digital twins, using the air traffic prediction.

In other words, the prediction of planned air traffic is used as negotiation support for planning.

In the example shown in FIG. 1, the electronic device for assisting in planning and dynamic negotiation of aircraft flight plan(s) includes an information processing unit U formed, for example, by a memory M and a processor P associated with memory M.

In the example shown in FIG. 1, acquisition, analysis, and update module 16, creation and optimization module 18, generation module 20, update module 22, and negotiation module 24 are each implemented in the form of software (e.g., an API (application programming interface) or alternatively a human-machine interface), or a software brick, executable by processor P. Memory M of electronic device 10 for assisting in planning and dynamic negotiation of aircraft flight plan(s) is then able to store acquisition, analysis, and update software, creation and optimization software, generation software, update software, and negotiation software. Processor P is then able to execute each of the software programs among the acquisition, analysis, and update software, the creation and optimization software, the generation software, the update software, and the negotiation software.

As a non-illustrated variant, acquisition, analysis, and update module 16, creation and optimization module 18, generation module 20, update module 22, and negotiation module 24 are each implemented in the form of a programmable logic component, such as an FPGA (Field Programmable Gate Array), or alternatively an integrated circuit, such as an ASIC (Application Specific Integrated Circuit).

When electronic device 10 for assisting in planning and dynamic negotiation of aircraft flight plan(s) is implemented in the form of one or more software programs, i.e., in the form of a computer program, also called a computer program product, it is further able to be recorded on a computer-readable medium (not shown). The computer-readable medium is, for example, a medium able to store electronic instructions and to be coupled to a bus of a computer system. By way of example, the readable medium is an optical disk, a magneto-optical disk, a ROM memory, a RAM memory, any type of non-volatile memory (for example, FLASH or NVRAM), or a magnetic card. A computer program including software instructions is then stored on the readable medium.

As an optional addition, negotiation module 24 includes at least: a first interaction entity 26 with first digital twin 12 representative of at least one air navigation service provider (also called ANSP agent), a second interaction entity 28 with second digital twin 14 representative of at least one air operations officer (also called airline agent), and an entity 30 for determining negotiation-aid elements.

According to this optional addition, first interaction entity 26 with first digital twin 12 representative of at least one air navigation service provider is at least configured to receive at least one item of information Dc representative of a capacity of the at least one air navigation service provider, the capacity being defined for each control zone of the airspace associated with the at least one air navigation service provider and for a predetermined time period.

For example, such a capacity is the number of sectors in the control zone of the airspace associated with the at least one air navigation service provider, and/or corresponds to constraints associated with the zone: waypoint, prohibited zone, maximum altitude, etc., and/or corresponds to predetermined intentions and priorities of the at least one air navigation service provider.

First interaction entity 26 with first digital twin 12 is further intended to supplement capacity forecasts by means of context data D, for example, acquired by acquisition module 16, and to provide a capacity forecast Pc₁ to entity 30 for determining negotiation-aid elements.

Such context data D are of a type belonging to the group including:
surveillance data provided by a cooperative surveillance system for air traffic control;
aeronautical publications;
meteorological data;
event data; and
historical data;
etc.

The surveillance data are, for example, provided by ADS-B (Automatic dependent surveillance-broadcast) data providers, such as the cooperative surveillance system for air traffic control “Flight Radar 24”, the Metron Aviation system, etc., and corresponding to all ADS-B data emitted by aircraft, either in real time or as historical data.

The aeronautical publication data are, for example, provided by air navigation service providers (ANSPs), by airports, by an air navigation safety organization, such as EUROCONTROL, for example, and correspond to all documents and website publications disseminated by these stakeholders.

The meteorological data are provided by weather forecast providers and correspond to weather forecasts.

The event data are, for example, provided via the Internet, newspapers, etc., and correspond to events having an impact on planning and dynamic negotiation of flight plan(s), such as an air traffic controller strike or airport staff strike, major sporting events, etc.

According to this optional addition, second interaction entity 28 with second digital twin 14 representative of at least one air operations officer is at least configured to receive at least one item of information representative of a demand of the at least one air operations officer (represented by the arrow going from second digital twin 14 to second interaction entity 28), the demand being defined by scheduled or ongoing flights (ongoing flights allowing the traffic prediction to be updated for inbound flights (i.e., that will begin soon)) associated with the at least one air operations officer (i.e., also called an airline dispatcher), a flight being representable by the departure airports, destination airports, and flight times, the set of routes the flight may take, the flight plan, the intentions, and the priorities attached to this flight (i.e., the flight plan(s) for the airlines and the sectorization/deconfliction strategy plan(s) on the ANSP side), etc.

Second interaction entity 28 with second digital twin 14 representative of at least one air operations officer is further intended to supplement demand forecasts by means of context data D, for example, acquired by the acquisition module 16 (of a type as mentioned above in relation to the first interaction entity 26), and to provide a demand forecast Pd₁ to entity 30 for determining negotiation-aid elements.

In other words, capacity forecast Pc₁ and demand forecast Pd₁ are estimates based on similar past situations.

Still according to this optional addition, entity 30 for determining negotiation-aid elements includes, according to a first so-called “basic” negotiation mode, a first tool 32 configured to determine, for each air navigation service provider, a demand-of-interest information representative of all flights crossing one of its control zones, and a second tool 34 configured to determine, for each air operations officer, a capacity-of-interest information grouping capacities of the zones crossed, by one or more flights.

For example, a demand-of-interest information may be represented by a set of flows, a list of flights and/or hotspots, a hotspot being an area of airspace where there is a risk for the efficiency of air operations (unexpected weather, congestion around an airport, problem at an airport, geopolitical problem, etc.).

More precisely, entity 30 for determining negotiation-aid elements, via tools 32 and 34 respectively, is intended to merge all forecasts to compute demands and capacities of interest using known basic processing, namely that demand forecasts passing through a control zone are merged to establish a demand of interest, and capacity forecasts on zones crossed by a demand are merged to establish a capacity of interest.

All these demands and capacities of interest are stored in a database BD.

The merging processing implemented by entity 30 for determining negotiation-aid elements, via tools 32 and 34, is intended to be triggered in two ways, namely synchronously according to a predetermined time period (for example, every hour), or asynchronously at each change of capacity and/or demand provided or if an event in the context occurs. Indeed, event data are likely to have an impact on demand or capacity.

Note that the context data are likely to include data other than the aforementioned surveillance, aeronautical publication, meteorological, or event data, such as any data that may help define capacities and demand, namely, for example, other data provided by each air navigation service provider (ANSP), by each air operations officer (i.e., airline), by airports, corresponding to flight plans filed with air navigation service providers (ANSPs), historical data, etc.

In other words, in such a first so-called “basic” negotiation mode, electronic device 10 for assisting in planning and dynamic negotiation of aircraft flight plan(s) according to the present invention (also called a gateway or platform) provides to each connected air navigation service provider (ANSP), machine-to-machine via first digital twin 12, its demand of interest, i.e., traffic forecasts for the control zone of the considered ANSP. Similarly, electronic device 10 for assisting in planning and dynamic negotiation of aircraft flight plan(s) provides to each air operations officer (i.e., airline), via second digital twin 14, its capacity of interest, i.e., capacity forecasts for its flights.

These data, namely demand of interest and capacity of interest, allow different stakeholders connected to electronic device 10 for assisting in planning and dynamic negotiation of aircraft flight plan(s) according to the present invention to negotiate, according to this so-called “basic” negotiation mode.

According to this so-called “basic” negotiation mode, electronic device 10 for assisting in planning and dynamic negotiation of aircraft flight plan(s) according to the present invention is intended to implement:
so-called “expert” or “rule-based” algorithmic models corresponding to mathematical functions or rules based on a priori knowledge; and/or
data-driven or machine-learning algorithmic models corresponding to machine algorithms trained to recognize situations that have already occurred. These models rely on statistical analysis and supervised or unsupervised machine learning methods.

Note that air navigation service providers connected via first digital twin 12 and air operations officers connected via second digital twin 14 are continuously notified of changes to their capacities or demands of interest and may therefore consult them.

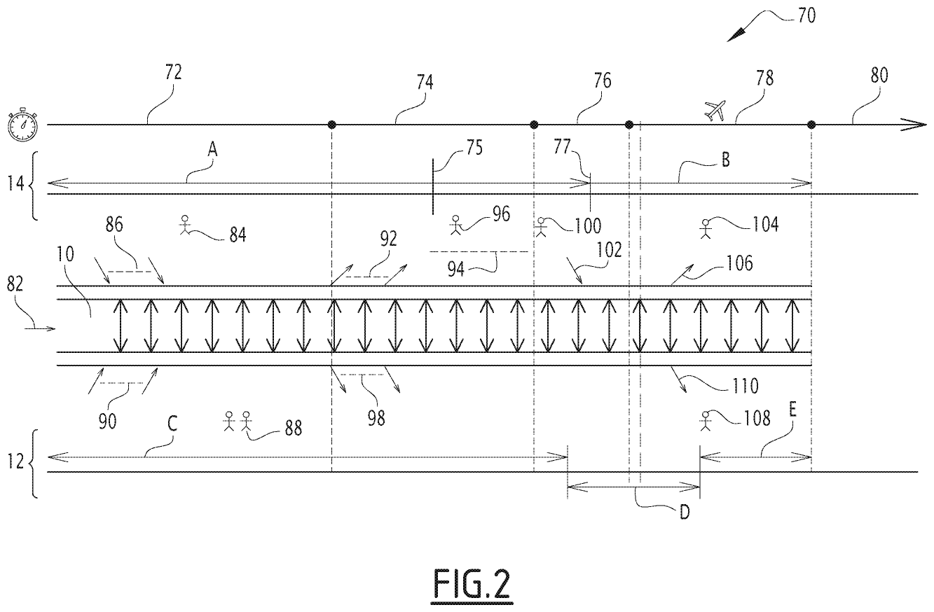

As illustrated hereinafter, notably in relation to FIG. 2, having this information, air navigation service providers (ANSPs), and air operations officers (i.e., airlines) may adapt their capacities and demands respectively.

As an optional addition, entity 30 for determining negotiation-aid elements is also configured to estimate evolution of traffic demand using an optimal filtering 40 belonging to the group including notably a Kalman filter, a particle filter, etc., or using a predetermined machine learning 42.

To do this, traffic demand is, for example, considered as a time series, like the number of aircraft occupying the sector each hour, which may then be characterized in order to predict its evolution. In this case, entity 30 for determining negotiation-aid elements is then, for example, configured to use optimal filtering methods, such as the Kalman filter or the particle filter, in order to estimate evolution of traffic demand.

To do this, it is postulated that the traffic-demand information evolves in a manner known a priori.

In this context, a state variable corresponding to the value of traffic demand a priori, stemming from expert knowledge x_{apriori,t}, and noted at time t, and a propagation model corresponding to the evolution of traffic demand over time stemming from the knowledge are considered.

Such a propagation model is a known law such as, for example, a piecewise linear function according to the period of the year or the day of the week, or alternatively a more complex function depending on factors such as aircraft type, weather, opening or closing of military zones, etc. This evolution may be modeled as: x_{apriori,t}=ƒ(x_{apriori,t-1})+wₜ, with ƒ being the propagation function, and wₜ called process noise, which corresponds to uncertainty about the evolution of the datum.

At certain times, observations x_{obs,t} concerning traffic demand are collected and are subject to a certain measurement error, noted as vₜ.

Particle filtering is based on a set of steps, namely first an initialization generating an initial set of particles

$${\{ {x}_{apriori , t}^{( i )} \}}_{i = 1}^{N} ,$$

which represents the initial estimate of the distribution of the state variable (traffic-demand level). Each particle has an equal initial weight, for

$${w}_{t}^{( i )} = \frac{1}{N}$$

number of particles, chosen according to a trade-off between computational complexity and precision.

Then, particle filtering includes a prediction consisting, for each particle, in applying the evolution model to predict the traffic-demand level at the next time t. If

$$f ( {x}_{apriori , t - 1}^{( i )} )$$

is the evolution model, the prediction for each particle becomes

$${x}_{BMM , t}^{( i )} = f ( {x}_{apriori , t - 1}^{( i )} ) + {w}_{t}^{( i )} ,$$

where

$${w}_{t}^{( i )}$$

is a sample drawn from the distribution of the process noise. Each particle propagates.

Then, particle filtering includes an update consisting, upon receiving a new observation x_{obs,t}, in updating the weightings of each particle as a function of the probability of that observation given the predicted state. This is often performed by calculating the probability density of given x_{obs,t} knowing

$${x}_{apriori , t}^{( i )}$$

and updating the weightings

$${w}_{t}^{( i )}$$

accordingly. The weightings update may be performed using, for example, the probability

$$p ( {x}_{o bs , t} \vert {x}_{apriori , t}^{( i )} ) .$$

Then, particle filtering includes resampling, to avoid the problem of particle degeneracy, where a few particles end up with a significantly higher weighting than the others. This involves selecting a new set of particles from the current set, where particles with higher weightings are more likely to be chosen.

Finally, particle filtering includes estimation as such, of the current traffic-demand level intended to be computed as a weighted average, such as the barycenter of the particle distribution after the update, i.e.,

$${\hat{x}}_{apriori , t}^{( i )} = {\sum }_{i = 1}^{N} {w}_{t}^{( i )} {x}_{apriori , t}^{( i )} .$$

Thus, traffic-demand data collected in operation allow the propagation model of traffic demand initially provided by expert knowledge to be updated.

As an alternative, another approach consists in training a machine-learning algorithm aimed at estimating traffic demand. In this case, a set of relevant data is collected. The data are considered relevant in the sense that they correlate with traffic demand.

Signals are also likely to be considered, such as trajectories, evolution of meteorological factors, etc. These signals are then used as input to a “model”, which aims to estimate traffic demand.

This model is likely to rely on deep-learning methods, but also on a combination of signal-processing and machine-learning techniques.

According to a first option, selection of discriminant markers is performed by machine learning without a priori selection. According to a second option, signal-processing is implemented to extract “features” or “signatures” from the collected processes. Then, a classifier, based on machine learning, uses these signatures to provide a decision on traffic demand.

Such features are likely to come from a frequency analysis of the signal, but also from a time-frequency or temporal analysis.

For frequency analysis, relevant signatures are generally the power value carried by frequency bands, or power ratios.

In a temporal analysis, one is generally interested in quantities such as the mean of the signal, its power, the zero-crossing rate, or the parameters of an a priori model. The aim is then to model how the samples of the signal are linked to one another, and to deduce the parameters of the associated model. Other types of features are related to signal regularity, which may be seen as the propensity for chaos. These techniques may rely on entropic analysis, such as Shannon entropy, spectral entropy, approximate entropy, the fractal dimension according to Higuchi, or multiscale entropic analysis.

In the case where the signal is monofractal, techniques such as detrended fluctuation analysis make it possible to estimate a quantity called the Hurst exponent, which characterizes the global regularity of a signal. These parameters are then used as input to a random learning, for example, of the “random forest” type, trained to associate a parameter set with a traffic demand.

Note that, to estimate evolution of traffic demand, a so-called “black box” solution is also likely to be relevant. Note that “black box” refers to estimating traffic demand, represented by a number of aircraft entering a sector per hour, as a function of that same datum in the past (i.e., traffic demand is viewed as a time series). Conversely, in a “white box” system, one would seek to know each trajectory or each phenomenon having an impact on whether a flight actually passes through a sector (weather, military zone, etc.) to integrate it in the aircraft count.

According to a second so-called “solicited” negotiation mode, entity 30 for determining negotiation-aid elements includes an optional third tool 36 configured to determine, by searching in a database of situation(s) similar to the current situation, for each air navigation service provider, a capacity solution representative of the capacity that best absorbs the demand of interest. A capacity solution corresponds, for example, to a set of rerouting constraints.

Still according to this second so-called “solicited” negotiation mode, entity 30 for determining negotiation-aid elements includes an optional fourth tool 38 configured to determine, for each air operations officer, a demand solution proposing at least one flight compatible with the capacity of interest, using a predetermined path-finding algorithm and a predetermined weighting based on at least one intention to implement a flight of the air operations officer. A demand solution corresponds to a rerouting compatible with prohibited zones along the considered route.

In other words, in such a second so-called “solicited” negotiation mode, electronic device 10 for assisting in planning and dynamic negotiation of aircraft flight plan(s) according to the present invention (also called a gateway or platform) provides, in addition, capacity solutions for air navigation service providers (ANSPs) and demand solutions for air operations officers (i.e., airlines). It is therefore an enriched negotiation mode compared to the first negotiation mode mentioned above, where electronic device 10 for assisting in planning and dynamic negotiation of aircraft flight plan(s) according to the present invention provides capacity or demand solutions that the ANSPs or airlines, respectively, may adopt.

Thus, electronic device 10 for assisting in planning and dynamic negotiation of aircraft flight plan(s) according to the present invention determines capacity solutions corresponding, for example, to a set of constraints for ANSPs enabling them to absorb a demand, and/or demand solutions corresponding, for example, to flights compatible with the constraints and optimized in terms of fuel consumption or flight time.

According to this so-called “solicited” negotiation mode, electronic device 10 for assisting in planning and dynamic negotiation of aircraft flight plan(s) according to the present invention implements an optimization that first uses capacity and demand data, in particular the intentions and priorities of each stakeholder, in order to extract optimization criteria therefrom, then uses the capacities and demands of interest, which represent the optimization constraints, and finally computes demand and/or capacity solutions using the optimization criteria and the optimization constraints.

According to this so-called “solicited” negotiation mode, electronic device 10 for assisting in planning and dynamic negotiation of aircraft flight plan(s) according to the present invention is intended to use, to determine capacity solutions (i.e., optimizations), a database that stores pairs (traffic demand over the zone, best capacity solution), filled over time by air traffic flow manager(s) (FMPs-Flow Management Position) according to their expertise, and the optimization solution consists in searching for similar situations to find the best capacity solutions.

According to this so-called “solicited” negotiation mode, electronic device 10 for assisting in planning and dynamic negotiation of aircraft flight plan(s) according to the present invention is intended to use, to determine demand solutions (i.e., optimizations), “path finding” type algorithms, such as A*, Dijkstra, etc., integrating constraints of crossed control zones with weight functions based on airline intentions (minimization of fuel or flight time).

As an optional addition, according to a third so-called “autonomous” negotiation mode, negotiation module 24 is also configured to make the negotiation autonomous by applying a predetermined set of rules for processing the proposed capacity solution and/or the proposed demand solution.

In other words, in such a third so-called “autonomous” negotiation mode, electronic device 10 for assisting in planning and dynamic negotiation of aircraft flight plan(s) according to the present invention (also called a gateway or platform) will react on behalf of an air navigation service provider (ANSP) and/or air operations officers (i.e., airlines) with respect to a change in capacities or demands of interest. It is therefore an even more enriched negotiation mode compared to the second negotiation mode mentioned above.

In such a third so-called “autonomous” negotiation mode, first interaction entity 26 with first digital twin 12 representative of at least one air navigation service provider optionally incudes a tool 44 for autonomous calculation of the capacity solution and uses for this purpose a set 46 of databases including notably a database 48 of possible constraints on the zone of interest of the at least one air navigation service provider (ANSP) and a base 50 of business rules specific to ANSPs. The business rules are used to automatically select, depending on the demand of interest, which possible constraints to apply. Constraint database 48 and business-rule base 50 are configured notably by the at least one air navigation service provider (ANSP), via first digital twin 12.

Moreover, in such a third so-called “autonomous” negotiation mode, second interaction entity 28 with second digital twin 14 representative of at least one air operations officer optionally includes a tool 52 for autonomous calculation of the demand solution and uses for this purpose a set 54 of databases including notably a database 56 of possible routes (i.e., a predetermined route catalog) and a base 58 of business rules specific to airlines. The business rules of base 58 are used to automatically select the best possible routes according to the capacity of interest. Route database 56 and business-rule base 58 are configured by the at least one air operations officer (i.e., airline).

As an optional addition, negotiation module 24 further includes: a simulation entity 60 of at least one other air navigation service provider not represented by first digital twin 12 while participating in the capacity of interest, and a simulation entity 62 of at least one other air operations officer not represented by second digital twin 14 while participating in the demand of interest.

In other words, according to this optional addition, air navigation service providers or air operations officers that are not directly interacting with device 10 for assisting in planning and dynamic negotiation of aircraft flight plan(s) are simulated in order to obtain, in particular, a reliable worldwide air traffic prediction.

More precisely, simulation entity 60 of at least one other air navigation service provider (ANSP) not represented by first digital twin 12 simulates the behavior of ANSPs that are not connected to device 10 for assisting in planning and dynamic negotiation of aircraft flight plan(s) but that participate in the capacity of interest of air operations officers (i.e., airlines) connected via second digital twin 14.

Simulation entity 60 of at least one other air navigation service provider (ANSP) is further intended to supplement simulated capacity forecasts by means of context data D (of a type as mentioned above in relation to first interaction entity 26), for example, acquired by acquisition module 16, and to provide a simulated capacity forecast Pc₂ to entity 30 for determining negotiation-aid elements.

Similarly, simulation entity 62 of at least one other air operations officer not represented by second digital twin 14 simulates the behavior of air operations officers (i.e., airlines) that are not connected to device 10 for assisting in planning but that participate in the demand of interest of ANSPs connected via first digital twin 12. To do this, simulation entity 62 takes as input the usual operations of air operations officers (i.e., airlines) that are not connected to device 10 for assisting in planning, and predicts the load that these operations will have on the sector.

Simulation entity 62 of at least one other air operations officer not represented by second digital twin 14 is further intended to supplement simulated demand forecasts by means of context data D (of a type as mentioned above in relation to first interaction entity 26), for example, acquired by acquisition module 16, and to provide a simulated demand forecast Pd₂ to entity 30 for determining negotiation-aid elements.

Whatever the negotiation mode implemented, namely basic, solicited or autonomous, its implementation depends on situation awareness and thus on the available data.

FIG. 2 is a representation 70 over time of machine-to-machine interactions of electronic device 10 for assisting in planning and dynamic negotiation of aircraft flight plan(s) according to the present invention, with first digital twin 12 representative of at least one air navigation service provider, and with second digital twin 14 representative of at least one air operations officer.

As illustrated by FIG. 2, electronic device 10 for assisting in planning and dynamic negotiation of aircraft flight plan(s) according to the present invention is positioned in the middle (i.e., at the center, as an intermediary) of a two-“pole” system 12 and 14. It is a tool for assisting in planning and automatic negotiation during this phase.

Several time phases 72, 74, 76, 78, and 80 are represented, namely a strategic phase 72 starting about 6 months before a given flight up to one week before the flight, followed by a pre-tactical phase 74 starting one week before the flight up to 1 day before the flight and including notably an instant 75 corresponding to an instant between 3 and 2 days before the flight, followed by a tactical phase 76 starting one day before the flight up to the flight and including an instant 77 between 8 and 2 hours before the flight, the flight as such being represented by phase 78, followed by a post-flight phase 80.

In parallel with the aforementioned time phases, activity of an air operations officer, represented by second digital twin 14, includes two periods A and B corresponding respectively to establishing the flight schedule A, followed by establishing B the plan for flight 78.

Also in parallel with the aforementioned time phases, activity of an air navigation service provider (ANSP), represented by first digital twin 12, includes three successive phases C, D, and E, respectively capacity management C, flow management D, and flight management E.

FIG. 2 illustrates how, over time, electronic device 10 for assisting in planning and dynamic negotiation of aircraft flight plan(s) according to the present invention interacts with first digital twin 12 representative of at least one air navigation service provider, and with second digital twin 14 representative of at least one air operations officer.

To do this, electronic device 10 for assisting in planning and dynamic negotiation of aircraft flight plan(s) according to the present invention first receives, as input, data 82 corresponding to the context data described previously, namely in particular historical data, weather data that become more refined as the day of operations approaches, information provided by ANSPs, planned events (sporting competitions, major climatic events), etc.

During strategic phase 72, electronic device 10 for assisting in planning and dynamic negotiation of aircraft flight plan(s) according to the present invention receives from second digital twin 14 representative of at least one air operations officer 84, a route prototype(s) 86 including a flight schedule, at least one airline route (i.e., an airline route catalog), at least one time slot given to the at least one air operations officer, at least one intention of the at least one air operations officer (i.e., flight optimization priority, minimization of the volume of fuel carried, and/or minimization of flight time).

During this same strategic phase 72, electronic device 10 for assisting in planning and dynamic negotiation of aircraft flight plan(s) according to the present invention also receives from at least one air navigation service provider (ANSP) 88, such as an airspace manager or a traffic flow management unit, via first digital twin 12, a traffic prototype 90 including ANSP constraints specific to the sector, ANSP historical data, a set of information useful for controllers or pilots regarding states of airspaces, such as the information from the NOP (Network Operations Portal) portal provided by Eurocontrol.

Electronic device 10 for assisting in planning and dynamic negotiation of aircraft flight plan(s) according to the present invention uses all of the aforementioned inputs 82, 86, and 90 received during strategic phase 72 to automatically provide, during pre-tactical phase 74, on the one hand predictions 92 of the most probable route(s) to approve during period 94 by an operator 96 of an operations control center (OCC), and on the other hand traffic predictions 98.

Predictions 92 of the most probable route(s) that at least one airline will take for upcoming flights comply with ATC constraints and may serve as a non-legal basis for creating a flight plan.

Such a complete view in terms of routes and traffic is generated in the planning phase (flights, routes, airline intentions), with increasing precision as the flight date approaches. Added to this is a prediction of anticipated hotspots for the sector based on data and traffic prediction. ANSPs may use this to plan their workload and also to simulate constraint changes, to observe the impact of such changes, and thus propose local constraint modifications to smooth traffic. These modifications are automatically transferred to air operations officers and enable new optimized flight routes to be generated.

During tactical phase 76, electronic device 10 for assisting in planning and dynamic negotiation of aircraft flight plan(s) receives from at least one air operations officer 100 (i.e., also called an airline dispatcher) at least one flight plan 102, then during flight phase 78, electronic device 10 for assisting in planning and dynamic negotiation of aircraft flight plan(s) transmits to a pilot 104, via second digital twin 14, a route proposal 106, and also transmits, via second digital twin 14, to an air traffic controller ATCO 108 the route proposal 110.

Note that it is difficult to propose a route without knowing a set of underlying parameters. A data-driven approach which, from historical flight schedule data 86, such as the pair formed by departure and arrival airport of a flight, the airline operating the flight, the aircraft type, the flight date, or the EOBT off-block departure time, makes it possible to estimate the flight plan, i a possible route, characterized by the element called ICAO field 15.

Such an approach combines feature engineering and machine-learning model training.

More precisely, during the inference phase, the route estimation functionality (ICAO flight plan element 15) leverages historical flight schedule data (the pair formed by the departure and arrival airport of a flight, the airline, the aircraft type, the date, or the estimated off-block time (EOBT)), optionally enriched with additional information (weather, distance, cost, optimal flight level, etc.).

These data are subjected to a feature engineering phase to extract relevant indicators (i.e., features) (for example, a number of direct segments, a frequency of use of certain routes, regulatory constraints).

A machine-learning model (for example, of the “random forest” type, of the gradient boosting type, such as XGBoost® or alternatively a large language model LLM) is then trained to predict, based on these features, the route best suited to the operational context.

Finally, a validation module (for example the “constraints checker®” tool) is likely to be used to verify the compliance of the proposed route with regulations and the constraints of the network manager, thus ensuring a recommendation that is both realistic and optimized.

As an alternative, another approach is likely to be based on clustering to characterize the habits of the considered airline.

An operations center equipped with electronic device 10 for assisting in planning and dynamic negotiation of aircraft flight plan(s) according to the present invention provides to at least one ANSP constraints (capacity, level caps) for its sectors in forecast, ensuring continuity between the upstream phase and the day of operations, creating a kind of preliminary flight plan.

As the day of operations approaches, electronic device 10 for assisting in planning and dynamic negotiation of aircraft flight plan(s) according to the present invention performs an automatic verification of the received flight plans.

If the flight plan is valid, electronic device 10 waits for concrete validation by the controller. If the flight plan is not valid, reliable alternatives for the sector are proposed to airlines without additional work for ANSPs.

On the air operations officer side, electronic device 10 for assisting in planning and dynamic negotiation of aircraft flight plan(s) according to the present invention therefore manages the air-route catalog completely, from long-term planning through to the day of operations. The air operations officer (i.e., also called an airline dispatcher) is assured that future routes and trajectories are optimized and automatically updated and comply with constraints. To do this, electronic device 10 relies on historical data and already available weather and ANSP data.

Electronic device 10 will take into account intentions and preferences of the airline(s) represented by digital twin 14 to formulate the preferred flight route in the current context. Electronic device 10 therefore performs an automatic negotiation with the digital equivalent 12 of the ANSP to output the preferred route adapted to the ATC constraints in force.

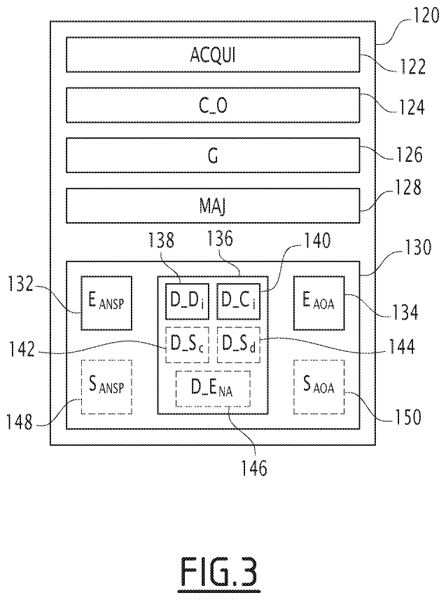

The operation of electronic device 10 for assisting in planning and dynamic negotiation of aircraft flight plan(s) will now be described with reference to FIG. 3, which schematically illustrates an example of implementing a method 120 for assisting in planning and dynamic negotiation of aircraft flight plan(s), by machine-to-machine connection, with first digital twin 12 representative of at least one air navigation service provider, and with second digital twin 14 representative of at least one air operations officer.

Method 120 for assisting in planning and dynamic negotiation of aircraft flight plan(s) is implemented by electronic device 10 for assisting in planning and dynamic negotiation of flight plan(s) previously described in relation to FIGS. 1 and 2.

Method 120 for assisting in planning and dynamic negotiation of aircraft flight plan(s) is an iterative method and includes at least one iteration of operations 122, 124, 126, 128, and 130 described below.

Indeed, the negotiation according to the present invention is carried out continuously, automatically, and takes into account updated constraints, airline intentions, weather data, etc.

Each iteration of method 120 for assisting in planning and dynamic negotiation of aircraft flight plan(s) first includes operation 122 of acquisition ACQUI (i.e. collection), analysis, and/or updating of data coming from a plurality of distinct sources including at least the digital twins, the data being likely to have an impact on planning and negotiation of flight plan(s).

Such data correspond notably to flight histories, air management portals, and stakeholders' intentions whether they be air navigation service providers or air operations officers on the airline side.

Operation 122 is followed by operation 124 of creation and optimization C_O of aeronautical routes compatible with air traffic control constraints associated with the data.

Next, method 120 for assisting in planning and dynamic negotiation of aircraft flight plan(s) includes an operation 126 of generation G, on a worldwide scale, of at least one air traffic prediction from the aeronautical routes.

Then, the method for assisting in planning and dynamic negotiation of aircraft flight plan(s) includes operation 128 of updating MAJ the aeronautical routes and the at least one air traffic prediction, as soon as at least one new datum is acquired or as soon as at least one datum is updated.

Finally, the current iteration includes operation 130 of intervention (i.e., electronic intervention), in the planning phase of flight plan(s), in a negotiation (i.e., an electronic negotiation) of flight plan(s) between the digital twins, using the air traffic prediction.

As an optional addition, operation 130 of intervention (i.e., electronic intervention), in the planning phase of flight plan(s), includes the sub-operations described below.

Operation 130 of intervention includes notably a sub-operation 132 EANSP of interaction with the first digital twin representative of at least one air navigation service provider, and a sub-operation 134 EAOA of interaction with the second digital twin representative of at least one air operations officer.

Moreover, according to this optional addition, operation 130 further includes a sub-operation 136 of determining demands and capacities of interest.

More precisely, sub-operation 136 includes a sub-sub-operation 138 of determination D_Di, for each air navigation service provider, of a demand-of-interest information item representative of all flights crossing one of its control zones, and a sub-sub-operation 140 of determination D_Ci, for each air operations officer, a capacity-of-interest information item grouping capacities of the zones crossed, by one or more flights.

Optionally (represented in dotted lines) as part of this optional addition, sub-operation 136 also includes a sub-sub-operation 142 of determination D_Sc, by searching in a database of situation(s) similar to the current situation, for each air navigation service provider, of a capacity solution representative of the capacity that best absorbs the demand of interest. A capacity solution corresponds, for example, to a set of rerouting constraints.

According to this same option, sub-operation 136 also includes a sub-sub-operation 144 of determination D_Sd, for each air operations officer, of a demand solution proposing at least one flight compatible with the capacity of interest, using a predetermined path-finding algorithm and a predetermined weighting based on at least one intention to implement a flight of the air operations officer. A demand solution corresponds to a rerouting compatible with prohibited zones along the considered route.

As an optional addition, sub-operation 136 also includes a sub-sub-operation 146 of determination D_ENA of elements configured to make negotiation autonomous by applying a predetermined set of rules for processing the proposed capacity solution and/or the proposed demand solution.

According to another optional addition, operation 130 of intervention also includes a sub-operation 148 of simulation SANSP of at least one other air navigation service provider not represented by the first digital twin while participating in the capacity of interest, and a sub-operation 150 of simulation SAOA of at least one other air operations officer not represented by the second digital twin while participating in the demand of interest.

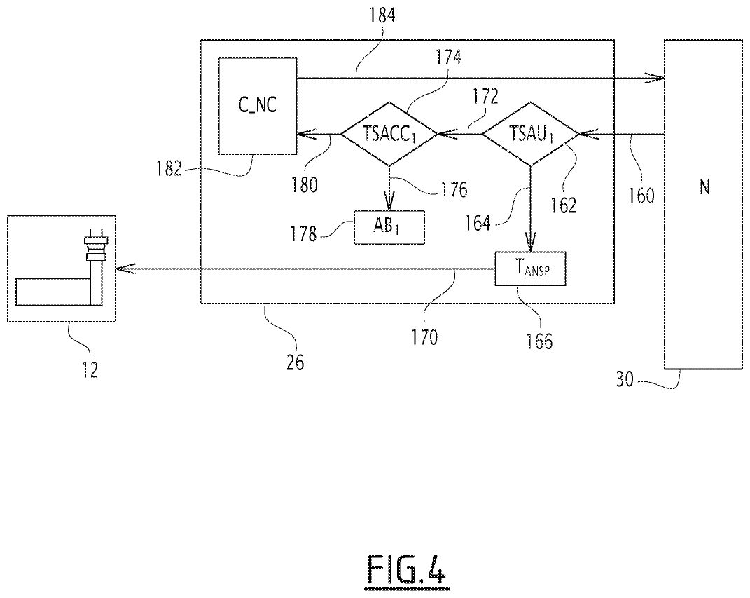

FIG. 4 illustrates optional operations of method 120 for assisting in planning and dynamic negotiation of aircraft flight plan(s) shown in FIG. 3, according to an autonomous negotiation mode, in the case of establishing an autonomous response to a capacity solution 160 (i.e., optimization) proposed by entity 30 for determining negotiation-aid elements N.

The operations relating to establishing an autonomous response are notably handled by first interaction entity 26 (also called ANSP agent) with first digital twin 12 representative of at least one air navigation service provider, previously introduced in relation to FIG. 1.

Establishing an autonomous response first includes an operation 162 of test TSAU₁, according to which first interaction entity 26 tests whether capacity solution 160 proposed by entity 30 for determining negotiation-aid elements N may be processed automatically or not.

If not, according to arrow 164, first interaction entity 26 implements an operation 166 of transmission TANSP of the capacity solution, according to arrow 170 to first digital twin 12 representative of at least one air navigation service provider (ANSP).

Conversely, if yes, according to arrow 172, first interaction entity 26 implements a second operation 174 of test TSACC₁ determining whether capacity solution 160 may be accepted or not.

If not, according to arrow 176, first interaction entity 26 implements an operation 178 of abandonment AB₁ of the capacity solution. If yes, according to arrow 180, first interaction entity 26 implements an operation 182 of calculation C_NC of a new capacity (i.e., updating the capacity) retransmitted according to arrow 184 to entity 30 for determining negotiation-aid elements N, to move the negotiation forward.

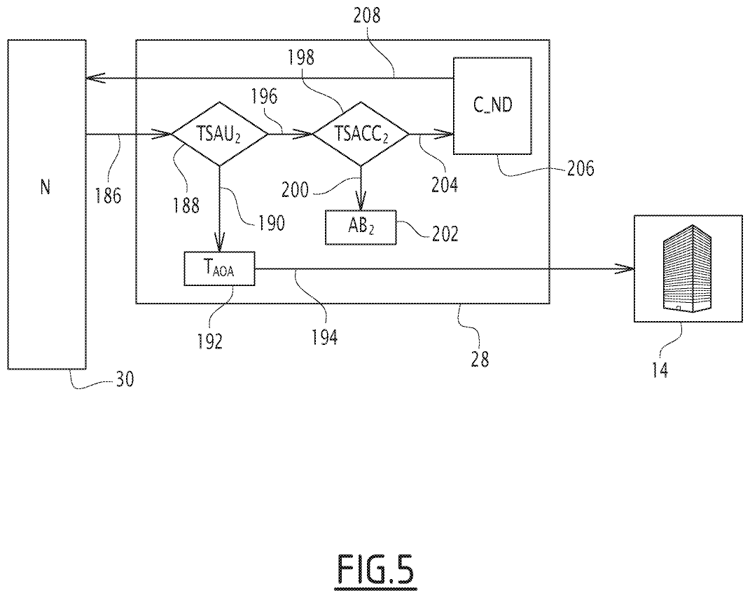

FIG. 5 illustrates optional operations of method 120 for assisting in planning and dynamic negotiation of aircraft flight plan(s) shown in FIG. 3, according to an autonomous negotiation mode, in the case of establishing an autonomous response to a capacity solution 160 (i.e., optimization) proposed by entity 30 for determining negotiation-aid elements N.

FIG. 5 illustrates optional operations of method 120 for assisting in planning and dynamic negotiation of aircraft flight plan(s) shown in FIG. 3, according to an autonomous negotiation mode, in the case of establishing an autonomous response to a demand solution 186 (i.e., optimization) proposed by entity 30 for determining negotiation-aid elements N.

The operations relating to establishing an autonomous response are notably handled by second interaction entity 28 (also called airline agent) with second digital twin 14 representative of at least one air operations officer, previously introduced in relation to FIG. 1.

Establishing such an autonomous response first includes an operation 188 of test TSAU₂, according to which second interaction entity 28 tests whether demand solution 186 proposed by entity 30 for determining negotiation-aid elements N may be processed automatically or not.

If not, according to arrow 190, second interaction entity 28 implements an operation 192 of transmission T_{AOA} of the demand solution, according to arrow 194 to second digital twin 14 representative of at least one air operations officer.

Conversely, if yes, according to arrow 196, second interaction entity 28 implements a second operation 198 of test TSACC₂ determining whether demand solution 186 may be accepted or not.

If not, according to arrow 200, second interaction entity 28 implements an operation 202 of abandonment AB₂ of the demand solution. If yes, according to arrow 204, second interaction entity 28 implements an operation 206 of calculation C_ND of a new demand (i.e., updating the demand) retransmitted according to arrow 208 to entity 30 for determining negotiation-aid elements N, to move the negotiation forward.

In other words, for the autonomous negotiation mode, the interaction entities, namely ANSP agent 26 and airline agent 28, are configured to take charge of negotiation, and respond autonomously to optimizations 160 and 186 proposed by entity 30 for determining negotiation-aid elements N using notably a predetermined configuration that defines:
the conditions under which an optimization 160 or 186 may be processed automatically (i.e., autonomously) by agent 26 or 28, or otherwise is presented directly to the ANSP or airline user via their digital twin 12 or 14 respectively;
the conditions under which the optimization processed by the agent is accepted or refused.
and if an optimization 160 or 186 is accepted (according to the aforementioned arrows 180 or 204), the automatic update of demand or capacity to entity 30 for determining negotiation-aid elements N.

Such a configuration is defined by users at air navigation service providers (ANSPs) or air operations officers (i.e., also called airline dispatchers), and at any time these users may act on the configuration and, consequently, on operation of device 10 for assisting in planning and dynamic negotiation of aircraft flight plan(s). For example, an air operations officer (i.e., also called an airline dispatcher) may add new intentions and specify the routes he wants to take in order to feed the negotiation.

This configuration defines, for example, in which time range an optimization (i.e., demand or capacity solution) may be accepted, and what types of optimizations may be accepted or processed autonomously. For example, for air navigation service providers (ANSPs), removal of certain constraints may be prohibited or require examination by the traffic flow manager (FMP—Flow Management Position).

Furthermore, the interaction entities, namely ANSP agent 26 and airline agent 28, may autonomously adapt their capacities or demands according to the evolution of the situation. For example, ANSP agent 26 may remove a constraint if the demand of interest in its sector falls below a predetermined threshold. Similarly, airline agent 28 may decide on a rerouting if the constraints of interest are too significant.

Such a mechanism based on a predetermined configuration specified by users at air navigation service providers (ANSPs) or air operations officers (i.e., also called airline dispatchers) enables local optimizations.

As illustrated previously in relation to FIG. 1, to do this, ANSP agent 26 uses a database 48 of possible constraints on its zone of interest and a base 50 of business rules specific to ANSPs. The business rules make it possible to decide, depending on demand, which possible constraints to apply. The constraint database and the rules base are configured by the ANSP via digital twin 12.

Similarly, as illustrated previously in relation to FIG. 1, to do this, airline agent 28 uses a database 56 of possible routes (the route catalog) and a base 58 of business rules specific to airlines. The business rules make it possible to decide the best possible routes according to the capacity of interest. The route database and the business-rule base are configured by the airline.

The person skilled in the art will understand that the invention is not limited to the described embodiments, nor to the particular examples of the description, the embodiments and variants mentioned above being likely to be combined with one another to generate new embodiments of the invention.

The present invention thus makes it possible, in a context of planning and dynamic negotiation of flight plan(s), to exchange information for predictability, to automatically obtain, as early as possible, optimized routes that are compatible with all constraints, therefore more likely to be accepted as such, and to use this estimate to launch an automatic negotiation between traffic stakeholders in order to optimize it and improve predictability on the day of operations.

The present invention enables global and scalable sharing of information and intent, even if imperfect, between the ground and the aircraft, with a view to taking this information into account and processing it in an overall manner. This represents a definite advantage over other information-sharing and state-of-the-art centralization initiatives that often remain localized to a region of the world.

The present invention proposes an automatic machine-to-machine negotiation to pre-process demands and submit only those having a high potential for acceptance, whereas the negotiations currently proposed facilitate negotiation but do not go as far as automating it, and leave a heavy workload on the various stakeholders in this negotiation who must validate or reject all requests made without pre-processing.

1. An electronic device for assisting in planning and dynamic negotiation of aircraft flight plan(s), by machine-to-machine connection with a first digital twin representative of at least one air navigation service provider, and with a second digital twin representative of at least one air operations officer, the device comprising:
an acquisition, analysis, and update module acquiring, analyzing, and updating data coming from a plurality of distinct sources comprising at least the digital twins, the data being likely to have an impact on planning and negotiation of flight plan(s);
a creation and optimization module creating and optimizing, based on the data, aeronautical routes compatible with the air traffic control constraints associated with the data;
a generation module generating, on a worldwide scale, at least one air traffic prediction from the aeronautical routes;
an update module updating the aeronautical routes and the at least one air traffic prediction, as soon as at least one new datum is acquired or as soon as at least one datum is updated; and
a negotiation module intervening in the planning phase of flight plan(s), in a negotiation of flight plan(s) between the digital twins, using the air traffic prediction.

2. The device according to claim 1, wherein the data comprise data provided by the digital twins and also context data of a type belonging to the group consisting of surveillance data provided by a cooperative surveillance system for air traffic control, aeronautical publications, meteorological data, event data and historical data.

3. The device according to claim 1, wherein said negotiation module comprises:
a first interaction entity with the first digital twin representative of at least one air navigation service provider, receiving at least one item of information representative of a capacity of the at least one air navigation service provider, the capacity being defined for each control zone of the airspace associated with the at least one air navigation service provider and for a predetermined time period;
a second interaction entity with the second digital twin representative of at least one air operations officer, receiving at least one item of information representative of a demand of the at least one air operations officer, the demand being defined by scheduled or ongoing flights associated with the at least one air operations officer; and
a determination entity determining negotiation-aid elements, determining, for each air navigation service provider, a demand-of-interest information item representative of all flights crossing one of its control zones, and determining, for each air operations officer, a capacity-of-interest information item grouping the capacities of the zones crossed.

4. The device according to claim 3, wherein said determination entity also estimates evolution of traffic demand using an optimal filtering belonging to the group consisting of Kalman filtering and particle filtering, or using a predetermined machine learning.

5. The device according to claim 3, wherein said determination entity determines, by searching in a database of situation(s) similar to the current situation, for each air navigation service provider, a capacity solution representative of the capacity that best absorbs the demand of interest, and determines, for each air operations officer, a demand solution proposing at least one flight compatible with the capacity of interest, using a predetermined path-finding algorithm and a predetermined weighting based on at least one intention to implement a flight of the air operations officer.

6. The device according to claim 5, wherein said negotiation module makes the negotiation autonomous by applying a predetermined set of rules for processing the proposed capacity solution and/or the proposed demand solution.

7. The device according to claim 5, wherein the demand solution is determined by said determination entity using a predetermined route catalog and a business-rule base specific to airlines, the catalog and the business-rule base being configured beforehand by the at least one air operations officer.

8. The device according to claim 3, wherein said negotiation module further comprises:
a simulation entity of at least one other air navigation service provider not represented by the first digital twin while participating in the capacity of interest; and
a simulation entity of at least one other air operations officer not represented by the second digital twin while participating in the demand of interest.

9. A method for assisting in planning and dynamic negotiation of aircraft flight plan(s), by machine-to-machine connection with a first digital twin representative of at least one air navigation service provider, and with a second digital twin representative of at least one air operations officer, the method being implemented by an electronic device for assisting in planning and dynamic negotiation of flight plan(s), the method comprising:
acquiring, analyzing, and/or updating data coming from a plurality of distinct sources comprising at least the digital twins, the data being likely to have an impact on planning and negotiation of flight plan(s);
creating and optimizing aeronautical routes compatible with the air traffic control constraints associated with the data;
generating, on a worldwide scale, at least one air traffic prediction from the aeronautical routes;
updating the aeronautical routes and the at least one air traffic prediction, as soon as at least one new datum is acquired or as soon as at least one datum is updated; and
intervening, in the planning phase of flight plan(s), in a negotiation of flight plan(s) between the digital twins, using the air traffic prediction.

10. A non-transient computer-readable memory storing a computer program which, when executed by a computer, causes the computer to implement a method according to claim 9.
